(19) United States
(12) Patent Application Publication
(10) Pub. No.: US 2026/0328859 A1
(43) Pub. Date: Oct. 22, 2026

(54) BATTERY CAPACITY ESTIMATION METHOD AND BATTERY CAPACITY ESTIMATION DEVICE

(71) Applicant: HONDA MOTOR CO., LTD., Tokyo (JP)

(72) Inventors: Yuki Ito, Tokyo (JP); Masafumi Yasuda, Tokyo (JP)

(21) Appl. No.: 19/530,416

(22) Filed: Feb. 5, 2026

(30) Foreign Application Priority Data
Feb. 19, 2025 (JP) 2025-025150

(51) Int. Cl. G01R 31/392; G01R 31/367; G01R 31/374

(52) U.S. Cl. CPC G01R 31/392; G01R 31/367; G01R 31/374

(57) ABSTRACT

A battery capacity estimation method is a method that estimate a deterioration state of a battery, and includes acquiring a capacity value, a current value, and a temperature of the battery in a battery capacity measurement and estimating a capacity true value of the battery by adding a capacity correction value calculated using Equation (1) described below to the capacity value.

$$dQ = {k}^{′} ( T ) I * \frac{100}{SOH} \qquad ( 1 )$$

(where dQ is a capacity correction value, T is a temperature (° C.), k′(T) is a constant at the temperature T, I is a current value, and SOH is a ratio (%) of a full charge capacity of the battery at a time of measurement relative to an initial full charge capacity of the battery.)

### CROSS-REFERENCE TO RELATED APPLICATION

Priority is claimed on Japanese Patent Application No. 2025-025150, filed Feb. 19, 2025, the content of which is incorporated herein by reference.

### BACKGROUND OF THE INVENTION

### Field of the Invention

The present invention relates to a battery capacity estimation method and a battery capacity estimation device.

### Description of Related Art

Conventionally, technologies for estimating a deterioration state of lithium-ion batteries are known. For example, a method for estimating a battery capacity using vehicle traveling data for in-vehicle lithium-ion batteries is known (for example, refer to Patent Document 1 below). However, because a rate at which lithium-ions diffuse between electrodes is slower at sub-zero temperatures than at a room temperature, reducing a battery capacity of a lithium-ion battery, there has been a problem that a diagnosis result for the capacity based on a room temperature is the same as that in a deteriorated state. It is known that an effect of a decrease in battery capacity due to sub-zero temperatures can be mitigated by, for example, estimating a resistance value at each temperature and correcting for this effect (for example, refer to Patent Document 2 described below).
[Patent Document 1] Japanese Unexamined Patent Application, First Publication No. 2023-48545
[Patent Document 2] Japanese Patent No. 6383500

### SUMMARY OF THE INVENTION

However, when battery deterioration progresses and battery capacity decreases, it is difficult to reproduce an effect of a sudden voltage drop at low temperatures due to lithium-ion diffusion rate-limiting on the decrease in battery capacity using resistance values alone, resulting in insufficient correction accuracy.

The aspects of the present invention have been devised in consideration of these circumstances, and one of objects of the present invention is to provide a battery capacity estimation method and battery capacity estimation device that can correct a decrease in battery capacity at low temperatures and reduce diagnostic errors in a capacity maintenance rate. This, in turn, contributes to energy efficiency.

To solve the problems described above, the present invention has adopted the following aspects.

[1] A battery capacity estimation method according to one aspect of the present invention estimates a deterioration state of a battery, and
in battery capacity measurement, estimates a capacity true value of the battery by acquiring a capacity value, a current value, and a temperature of the battery, and adding a capacity correction value calculated using the following equation (1) to the capacity value.

$$dQ = {k}^{′} ( T ) I * \frac{100}{SOH} \qquad ( 1 )$$

(where dQ is the capacity correction value, T is the temperature (° C.), k′(T) is a constant at a temperature T, I is the current value, and SOH is a ratio (%) of a full charge capacity of the battery at a time of measurement relative to an initial full charge capacity of the battery)

According to the aspect [1] described above, it is possible to correct the decrease in battery capacity at low temperatures, and reduce diagnostic errors in the capacity maintenance rate.

[2] In the aspect [1] described above, k′(T) may also be a coefficient calculated on the basis of an actual measured value of battery capacity at each temperature at a current value i₀ in an initial state of the battery.

According to the aspect [2] described above, even if it is difficult to accurately measure or estimate a lithium-ion diffusion coefficient or the maximum lithium concentration of the battery depending on a type or an intended use of the battery, it is possible to correct the decrease in battery capacity at low temperatures and reduce diagnostic errors in the capacity maintenance rate by using k′(T) described above.

[3] In the aspect [1] or [2] described above, k′(T) may be a coefficient calculated by performing linear interpolation on a plot in which the capacity correction value dQ of the battery at each temperature at a current value i₀ in an initial state of the battery is used as the vertical axis and the temperature is used as the horizontal axis.

According to the aspect [3] described above, even if it is difficult to accurately measure or estimate the lithium-ion diffusion coefficient or the maximum lithium concentration of the battery depending on a type or an intended use of the battery, by using the k′(T) described above, it is possible to correct the decrease in battery capacity at low temperatures and reduce diagnostic errors in the capacity maintenance rate.

[4] A battery capacity estimation device according to another aspect of the present invention estimates a capacity true value of the battery according to any one of the aspects [1] to [3] described above.

According to the aspect [4] described above, it is possible to correct the decrease in battery capacity at low temperatures and reduce diagnostic errors in the capacity maintenance rate.

According to the aspect of the present invention, it is possible to correct the decrease in battery capacity at low temperatures and reduce diagnostic errors in the capacity maintenance rate.

### BRIEF DESCRIPTION OF THE DRAWINGS

FIG. 1 is a diagram which shows a battery capacity estimation device according to an embodiment of the present invention.

### DETAILED DESCRIPTION OF THE INVENTION

Hereinafter, a battery capacity estimation method according to an embodiment of the present invention will be described.

### [Battery Capacity Estimation Method]

A battery capacity estimation method according to one embodiment of the present invention is a battery capacity estimation method that estimates a deterioration state of a battery, and is a method for estimating a battery capacity true value by acquiring, in a battery capacity measurement, a capacity value, a current value, and a temperature of the battery and adding a capacity correction value calculated using the following equation (1) to the capacity value.

$$dQ = {k}^{′} ( T ) I * \frac{100}{SOH} \qquad ( 1 )$$

(where dQ is the capacity correction value, T is the temperature (° C.), k′(T) is a constant at the temperature T, I is the current value, and SOH is a ratio (%) of a full charge capacity value of the battery at a time of measurement relative to an initial full charge capacity value of the battery.)

k′(T) is a coefficient calculated on the basis of an actual measured value Q(T) of battery capacity at each temperature for a current value i in an initial state of the battery.

A method for calculating k′(T) will be described below. A charge and discharge test is performed at different temperatures (t₁, . . . t_{N}) at a current value i₀ in the initial state (SOH=100%) of the battery and an actual measured value of capacity Q(tₙ) for each temperature is measured (where N is an integer greater than or equal to 2 and n is an integer between 1 and N). Next, a difference ΔQₜₙ=Q₀−Q(tₙ) between each measured actual measured value Q(tₙ) and an actual measured value of capacity Q₀ at a reference temperature (for example, 25° C.) is calculated. A plot is created using the obtained ΔQₜ₁, . . . ΔQ_{tN} as the vertical axis and temperature as the horizontal axis, and interpolation is used to obtain a graph of ΔQ with respect to temperature. The coefficient k′(T) can be calculated by dividing a value of ΔQ at the temperature T by the current value i₀ in this graph. Note that when k′(T) is calculated, a regression analysis may be performed using ΔQ as a response variable and temperature as an explanatory variable, and k′(T) may be calculated based on a graph of an obtained approximate line or a curve.

The current value i can be defined based on a current value of measurement data used to estimate the capacity. When a vehicle is considered, an upper limit, an average, a median, a root mean square (RMS) value, or the like of the current value of the measurement data can be used. The RMS of a current, also known as a root mean square, is an index that represents an effective value of the battery. When the current value i significantly exceeds the current value of the measurement data, the capacity will be underestimated. For this reason, it is preferable to use a value within a range not exceeding the current value of the measurement data, and it is preferable to use the upper limit.

The SOH is a capacity maintenance rate of a battery at a time of measurement.

The capacity correction value dQ can also be expressed by the following equation (2):

$$dQ = \frac{1}{D ( T )} * \frac{K ( T )}{{C}_{max}} * I * \frac{100}{SOH} \qquad ( 2 )$$

(where D(T) is a diffusion coefficient of lithium ions in the battery at the temperature T (° C.), K is a coefficient, I is the current value, Cₘₐₓ is a maximum lithium concentration in the battery, and SOH is a ratio (%) of the full charge capacity value of the battery at the time of measurement relative to the initial full charge capacity value of the battery.)

D(T) can be estimated using various electrochemical measurement methods, for example, constant current intermittent titration (GITT). Because D(T) is dependent on temperature, it is desirable to measure it over a wide temperature range, from low to room temperature.

Cₘₐₓ can be defined as a maximum amount of lithium that can be charged and discharged in the battery. In many cases, the positive electrode capacity is smaller than the negative electrode capacity, so in such cases, Cₘₐₓ can be defined from the usable capacity of the positive electrode.

K(T) can be calculated in the same manner as k′(T). First, in the initial state (SOH=100%), a charge and discharge test is performed at different temperatures (t₁, . . . t_{N}) at a predetermined current value i₀, and the actual measured value of capacity Q(tₙ) for each temperature is measured (where N is an integer greater than or equal to 2 and n is an integer between 1 and N). Next, a difference ΔQₜₙ=Q₀−Q(tₙ) between each measured actual measured value Q(tₙ) and the actual measured value of capacity Q₀ at the reference temperature (for example, 25° C.) is calculated. A plot is created using the obtained ΔQₜ₁, . . . ΔQ_{tN} as the vertical axis and temperature as the horizontal axis, and interpolation is used to obtain a graph of ΔQ with respect to temperature. In this graph, the coefficient k′(T) is calculated by dividing the value of ΔQ at the temperature T by the current value i₀. The coefficient k′(T) obtained in this manner is equal to 1/D(T)×K(T)/Cₘₐₓ, so that K(T) can be calculated based on D(T) and Cₘₐₓ at the temperature T. Note that when k′(T) is calculated, a regression analysis may be performed using ΔQ as a response variable and temperature as an explanatory variable, and 1/D(T)×K(T)/Cₘₐₓ may be calculated based on the obtained approximate line or curve graph to calculate K(T).

The current value I can be defined based on the current value of the measurement data used to estimate the capacity. When the vehicle is considered, the upper limit, average, median, RMS value, or the like of the current value used in the estimation can be used. The root mean square (RMS) of a current, also known as the root mean square, is an index that represents an effective value of a battery. When the current value I significantly exceeds the current value of the measurement data, the capacity will be underestimated. Therefore, it is preferable to use a value within a range not exceeding the current value of the measurement data, and it is preferable to use the upper limit.

Measuring the capacity correction value dQ of a deteriorating battery requires a durability test at many levels and over a long period of time, and it is not realistic to determine a value of K corresponding to the deterioration state by fitting measurement values. Therefore, in a deteriorating state of the battery, it is assumed that Cₘₐₓ decreases in accordance with capacity deterioration, and the dQ of the deteriorating battery can be estimated by correcting Cₘₐₓ by multiplying it by a measurement value of the immediately preceding capacity maintenance rate.

It is described that how the capacity correction value dQ is expressed by Equation (2) described above.

The following equation (3) is established based on a diffusion equation on a surface of an active material particle of a radius r.

$$- D \frac{\partial c}{\partial γ} = js \qquad ( 3 )$$

(where D is a diffusion coefficient of a lithium-ion, c is a concentration of the lithium-ion, r is a radius of the active material particle, and js is a flux of the lithium-ion (mol/m²/s).)

Based on the above equation (3), assuming a diffusion-limited state (c=Cₘₐₓ) in which all lithium sites on the surface of the active material particle are filled, an amount of lithium that cannot be accommodated (i.e., the amount of lithium that is not fully discharged) x is considered to have a relationship shown in the following equation (4):

$$x ∝ \frac{r}{{Dc}_{max}} {j}_{s} \qquad ( 4 )$$

Therefore, the amount of lithium x that is not be fully discharged due to the lithium-ion diffusion coefficient D(T) in the battery at temperature T(K) can be expressed by the following equation (5) using a proportionality coefficient k:

$$x = \frac{1}{D} * \frac{kr}{{C}_{max}} * \frac{I}{AF} \qquad ( 5 )$$

Note that since js=I/F/A (F is a Faraday coefficient (c/mol) and A is a surface area (m²)), js is expressed as I/AF in Equation (5) described above.

Here, when the amount of lithium x is converted into units of discharge capacity Q and r/AF, which is a fixed value but difficult to measure, is expressed by the proportionality coefficient K, the capacity correction value dQ can be expressed using a simplified equation of Equation (2) described above.

Depending on a type or an intended use of a battery, it may be difficult to measure or estimate accurate values of D(T) and Cₘₐₓ. Therefore, the battery capacity estimation method of the present embodiment regards 1/D(T)×K(T)/Cₘₐₓ as a single coefficient k′(T) and uses a capacity correction value calculated using Equation (1) described above.

The battery capacity estimation method of the present embodiment acquires a capacity value, a current value, and a temperature of the battery in the battery capacity measurement. The capacity correction value dQ calculated using Equation (1) or (2) described above is added to the capacity value obtained in the battery capacity measurement, specifically a capacity maintenance rate of the battery, to estimate a capacity true value of the battery, specifically a true capacity maintenance rate of the battery.

Batteries whose capacity true value can be estimated using the battery capacity estimation method of the present embodiment are, for example, secondary batteries that can be repeatedly charged and discharged, such as lithium-ion batteries. A positive electrode active material constituting a positive electrode of the battery is a material containing at least one of materials such as nickel cobalt manganese (NCM), nickel cobalt aluminum (NCA), lithium cobalt oxide (NCO), lithium ferrophosphate (LFP), and lithium manganese oxide (LMO), while a negative electrode active material constituting a negative electrode of the battery can be a metal that forms an alloy with lithium or an alloy containing such a metal. For example, the negative electrode active material is a material containing at least one of materials such as a lithium metal, lithium transition metal oxides such as lithium titanate oxide (LTO), hard carbon, and graphite, and may further contain silicon, silicon oxide, silicon carbide, or other silicon-based compounds. The battery may also be a battery pack, such as a cassette-type battery pack, that is detachably attached to the vehicle.

### [Battery Capacity Estimation Device]

A battery capacity estimation device according to one embodiment of the present invention is a device that estimates a battery capacity true value using the battery capacity estimation method of the embodiment described above.

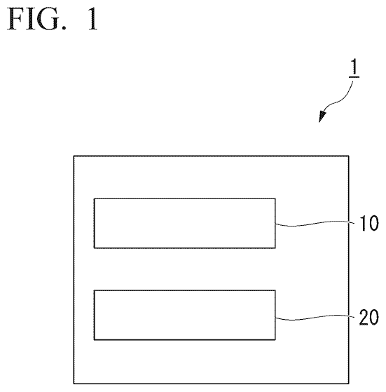

FIG. 1 is a diagram which shows an example of a configuration of a battery capacity estimation device according to the present embodiment.

As shown in FIG. 1, a battery capacity estimation device 1 includes, for example, an acquisition unit 10 and a capacity estimation unit 20.

The acquisition unit 10 performs a battery capacity measurement. In the battery capacity measurement, in addition to measuring a capacity value of a battery, a current value of the battery and a temperature of the battery are acquired.

The capacity estimation unit 20 estimates the capacity true value of the battery by adding the capacity correction value calculated using Equation (1) described above to the capacity value of the battery acquired by the acquisition unit 10.

The battery capacity estimation device of the present embodiment can estimate the capacity true value of the battery using the battery capacity estimation method of the embodiment described above.

### Example

The present invention will be described in more detail below using examples, but the present invention is not limited to the following examples.

### Example

### “Battery Manufacturing”

A battery was manufactured, including a positive electrode containing NCM811 as the positive electrode active material and a negative electrode made of graphite.

“Acquisition of actual measured value of capacity and ΔQ in initial state of battery”

Lithium-ion battery cells for a charge and discharge test were manufactured and subjected to predetermined activation processing.

Next, the lithium-ion battery cells for a charge and discharge test were charged to an upper voltage limit using a current of 1/3 C, then subjected to constant-voltage charging for one hour. After waiting for 30 minutes in an open-circuit state, they were discharged to a lower voltage limit using a current of 1/3 C to perform the charge and discharge test. This charge and discharge test was performed at temperatures of 25° C., 0° C., −10° C., and −25° C., and the capacity actual values Q(25), Q(0), Q(−10), and Q(−25) were acquired at each temperature. This work was performed on a plurality of battery cells, and average values at each temperature Qₘ(25), Qₘ(0), Qₘ(−10), and Qₘ(−25) were calculated. Using 25° C. as the reference temperature, a difference ΔQ(t′)=Qₘ(25)−Qₘ(t′) (t′ is each temperature of 25° C., 0° C., −10° C., and −25° C.) between a capacity average value Qₘ(25) at the reference temperature and a capacity average value at each temperature was obtained.

### “Calculation of Correction Value of Capacity Correction Value dQ of Battery”

### Correction Method (1)

Values ΔQ(25), ΔQ(0), ΔQ(−10), and ΔQ(−25) obtained above were plotted using ΔQ as the vertical axis and temperature as the horizontal axis. Linear interpolation was then performed on the plot to obtain a graph. A value of the vertical axis at the temperature T on the obtained graph was divided by i₀ to obtain k′(T).

Equation (1) based on the calculated k′(T) is used to calculate the capacity correction value dQ at temperatures of 25° C., 0° C., −10° C., and −25° C. when the current value I=5A using the correction method (1).

### Correction Method (2)

K(T) in Equation (2) was calculated based on the values of ΔQ(25), ΔQ(0), ΔQ(−10), and ΔQ(−25) obtained using the method described above. The values of ΔQ(25), ΔQ(0), ΔQ(−10), and ΔQ(−25) were plotted using ΔQ as the vertical axis and temperature as the horizontal axis, and linear interpolation was performed on the plot to obtain a graph. The coefficient K(T) was obtained by dividing the vertical axis value at the temperature T on the obtained graph by i₀ and multiplying this value by the maximum lithium concentration Cₘₐₓ and the lithium-ion diffusion coefficient D(T) at the temperature T. Note that Cₘₐₓ was the capacity density of the positive electrode (Ah/m2), and the lithium-ion diffusion coefficient D(T) within the battery was calculated.

A correction method (2) based on the calculated K(T) is used to calculate the capacity correction value dQ at temperatures 25° C., 0° C., −10° C., and −25° C. when the current value I=5A using the correction method (2).

### “Estimation of Capacity Maintenance Rate in Deterioration State of Battery”

When the capacity maintenance rate in a battery deterioration state is estimated, the estimation of the capacity maintenance rate is performed at temperatures of 0° C. and −10° C. for cases where the true capacity maintenance rate is 90% and 80%. Here, the true capacity maintenance rate is a capacity maintenance rate at a temperature of 25° C. in the deterioration state of the battery, and was calculated by dividing an actual measured value of capacity at the temperature of 25° C. in the deterioration state of the battery by an actual measured value of capacity at the temperature of 25° C. in the initial state of the battery.

For data used to calculate an estimated value of the capacity maintenance rate before correction, a corresponding battery cell is given charge and discharge loads while a vehicle was traveling to simulate a use environment in the vehicle. The load was input with a battery charge and discharge output in a plurality of traveling modes such as a WLTC mode, an LA4 mode, a US06 mode, and an NADC mode, and a voltage, a current, and temperature data were acquired.

Using these data, a filter current value was set to 5A, and an estimated value of the capacity maintenance rate was set to an estimation value of an uncorrected capacity maintenance rate by the method described in Patent Document 1.

A value obtained by adding the capacity correction value dQ obtained using correction method (1) or correction method (2) to the estimated value of the uncorrected capacity maintenance rate estimate was set as an estimated value of a corrected capacity maintenance rate of the example.

The capacity correction value dQ was calculated using Equation (1) or (2) described above. A method using Equation (1) above is referred to as Correction method (1), and a method using Equation (2) above is referred to as Correction method (2).

Table 1 shows an actual measured value of the capacity correction value dQ and a correction value of the capacity correction value dQ calculated using Correction method (1) or Correction method (2). Table 2 shows k′(T), which was used to calculate the correction value of the capacity correction value dQ using Correction method (1), and K(T) and D(T), which were used to calculate the correction value of the capacity correction value dQ using Correction method (2). Table 3 shows estimated capacity maintenance rate values for cases with no correction, cases with correction using Correction method (1), and cases with correction using correction method (2).

TABLE 1

| | |
|---|---|
| dQ actual | |
| measured | dQ correction value (%) |

| Temperature | value | Correction | Correction |
|---|---|---|---|
| (°C) | (%) | method (1) | method (2) |
| 25 | 0 | 0 | 0 |
| 0 | 0.8 | 0.5 | 0.8 |
| −10 | 4.3 | 3.5 | 3.3 |
| −20 | 6.6 | 6.6 | 6.6 |

TABLE 2

| | | |
|---|---|---|
| | Correction | |
| Temperature | method (1) | Correction method (2) |

| (°C) | k′(T) | K(T) | D(T)(m²/s) |
|---|---|---|---|
| 25 | 0 | 0 | 2.6 × 10⁻¹⁵ |
| 0 | 0.15 | 8.5 × 10⁻¹⁶ | 2.5 × 10⁻¹⁵ |
| −10 | 0.65 | 4.8 × 10⁻¹⁴ | 1.8 × 10⁻¹⁵ |
| −20 | 1.31 | 2.5 × 10⁻¹³ | 3.8 × 10⁻¹⁵ |

TABLE 3

| | | Estimated value of capacity | | |
|---|---|---|---|---|
| True capacity | | maintenance rate (%) | | |
| maintenance | Temperature | No | Correction | Correction |
| rate (%) | (°C) | correction | method (1) | method (2) |
| 90 | 0 | 81 | 86 | 85 |
| 90 | −10 | 77 | 84 | 83 |
| 80 | 0 | 70 | 75 | 75 |
| 80 | −10 | 65 | 73 | 72 |

The correction method (1) or correction method (2) are used based on results shown in Tables 1 and 3, thereby enabling estimation of a capacity maintenance rate using a numerical value closer to a true capacity maintenance rate than when no correction is made.

The above describes in detail the embodiment of the present invention, but the present invention is not limited to the embodiment described above. Various modifications and changes are possible within a range of the gist of the present invention as set forth in the claims.

What is claimed is:

1. A battery capacity estimation method that estimates a deterioration state of a battery, comprising:
acquiring a capacity value, a current value, and a temperature of the battery in a battery capacity measurement, and estimating a capacity true value of the battery by adding capacity correction value calculated using Equation (1) described below to the capacity value.
$$dQ = {k}^{′} ( T ) I * \frac{100}{SOH} \qquad ( 1 )$$
(where dQ is a capacity correction value, T is a temperature (° C.), k′(T) is a constant at the temperature T, I is a current value, and SOH is a ratio (%) of a full charge capacity of the battery at a time of measurement relative to an initial full charge capacity of the battery.)

2. The battery capacity estimation method according to claim 1,
wherein k′(T) is a coefficient calculated based on the actual measured value of the battery capacity at each temperature at a current value i₀ in the initial state of the battery.

3. The battery capacity estimation method according to claim 1,
wherein k′(T) is a coefficient calculated by performing linear interpolation on a plot in which a capacity correction value of a battery at each temperature at a current value i₀ in the initial state of the battery is used as the vertical axis, and temperature is used as the horizontal axis.

4. A battery capacity estimation device configured to estimate a battery capacity true value in the battery capacity estimation method according to claim 1.
